(19) United States
(12) Patent Application Publication
(10) Pub. No.: US 2010/0006837 A1
(43) Pub. Date: Jan. 14, 2010

(54) COMPOSITION FOR OXIDE SEMICONDUCTOR THIN FILM, FIELD EFFECT TRANSISTOR USING THE COMPOSITION AND METHOD OF FABRICATING THE TRANSISTOR

(75) Inventors: Doo Hee Cho, Daejeon (KR); Sang Hee Park, Daejeon (KR); Chi Sun Hwang, Daejeon (KR); Hye Yong Chu, Daejeon (KR); Kyoung Ik Cho, Daejeon (KR); Shin Hyuk Yang, Gyeonggi-do (KR); Chun Won Byun, Daejeon (KR); Eun Suk Park, Daejeon (KR); Oh Sang Kwon, Daejeon (KR); Min Ki Ryu, Seoul (KR); Jae Heon Shin, Daejeon (KR); Woo Seok Cheong, Daejeon (KR); Sung Mook Chung, Gyeonggi-do (KR); Jeong Ik Lee, Gyeonggi-do (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/496,558

(22) Filed: Jul. 1, 2009

(30) Foreign Application Priority Data
Jul. 9, 2008 (KR) 10-2008-0066488
Jul. 22, 2008 (KR) 10-2008-0071163

(51) Int. Cl. H01L 29/786; H01L 21/336; H01B 1/08

(52) U.S. Cl. 257/43; 438/104; 252/519.51; 257/E29.296; 257/E21.411

(57) ABSTRACT

Provided are a composition for an oxide semiconductor thin film, a field effect transistor using the same and a method of fabricating the field effect transistor. The composition includes an aluminum oxide, a zinc oxide, an indium oxide and a tin oxide. The thin film formed of the composition is in amorphous phase. The field effect transistor having an active layer formed of the composition can have an improved electrical characteristic and be fabricated by a low temperature process.

### CROSS-REFERENCE TO RELATED APPLICATION

This application claims priority to and the benefit of Korean Patent Application No. 10-2008-0066488, filed Jul. 9, 2008 and Korean Patent Application No. 10-2008-0071163, filed Jul. 22, 2008, the disclosure of which is incorporated herein by reference in its entirety.

### BACKGROUND

1. Field of the Invention

The present invention relates to a composition for an oxide semiconductor thin film 3 which can be used as an active layer for various semiconductor devices such as a field effect transistor, a field effect transistor using the same, and a method of fabricating the field effect transistor.

2. Discussion of Related Art

Materials used for conventional semiconductor thin film include Group IV elements such as silicon (Si) and germanium (Ge), Groups III-V compounds such as GaAs, and Groups II-VI compounds such as CdS. Generally, these conventional semiconductor materials do not transmit visible rays or strongly exhibit a particular color, due to a small band gap. However, because oxide semiconductors are transparent in a visible ray range, their application to novel electronic products is anticipated. An example of the oxide semiconductors is zinc oxide (ZnO), which is one of the Groups II-VI compounds. The zinc oxide has been studied for a long time, and is approaching commercialization since its field effect mobility, which is a major physical property of semiconductors, is higher than that of amorphous silicon. However, the zinc oxide has physical properties that are easily changed according to the fabrication process, and has low durability and weak resistance to environmental changes.

There are several patents disclosing transparent semiconductor compositions using oxides in addition to zinc oxide.

Japanese Patent Publication No. 2000-150900 discloses a transparent semiconductor thin film having compositions of ZnO, CdO, CdZnO and MgZnO.

Japanese Patent Publication No. 2004-103957 discloses a semiconductor thin film composition of InMO₃(ZnO)ₘ (wherein, M is Fe, Ga or Al, and m is an integer ranging from 1 to 50).

U.S. Patent Publication No. 2003-218221A1 discloses a thin film transistor using an oxide, which substantially serves as an insulator selected from ZnO and SnO₂, as an active layer, and U.S. Patent Publication No. 2003-218222A1 discloses a transparent thin film transistor using a transparent oxide selected from ZnO, SnO₂ and In₂O₃ as an active layer.

U.S. Patent Publication No. 2005-199879A1 discloses a semiconductor technique using an oxide having two components selected from CdO, SrO, CaO and MgO as a channel.

Further, in U.S. Patent Publication No. 2005-199880A1, a semiconductor composition of AxBxCxO (A: Zn or Cd, B: Ga or In, and C: Ge, Sn or Pb) and a device are disclosed by Hewlett-Packard, and in U. S. Patent Publication No. 2006-163655A1, a semiconductor material having a composition of AxBxO (A: Cu, Ag or Sb, and B: Cu, Ag, Sb, Zn, Cd, Ga, In, Sn or Pb) and a device are disclosed by Hewlett-Packard.

Recently, in Japanese Patent Publication No. 2007-123702, a thin film transistor having an active layer, which is formed by stacking one a selected from oxide semiconductors such as ZnO, SnO₂, In₂O₃ and Zn₂SnO₄, and a thin interlayer oxide b exhibiting a tunneling effect is disclosed by Toppan printing.

In Japanese Patent Publication Nos. 2007-142195 and 2007-142196, a display device having a thin film transistor formed of an amorphous oxide layer containing ZnO and In₂O₃, and an amorphous oxide semiconductor containing ZnO and SnO₂ are respectively disclosed by Idemitsu Kosan.

In U.S. Patent Publication No. 2006-0113539A1, a field effect transistor, in which an active layer is formed of amorphous materials having oxide compositions of In—Zn—Sn—O and In—Zn—Ga—O is disclosed by Cannon.

Besides the above-mentioned techniques, research on thin film transistors having active layers formed of In₂O₃—ZnO— and SnO₂—ZnO-based semiconductor materials has been widely conducted, and an In—Ga—Zn—O-based thin film transistors have also been actively researched and almost commercialized.

Exemplary applications of a thin film transistor using an oxide semiconductor thin film as a channel active layer may include a back-plane device for various active-matrix display panels such as an active-matrix organic light emitting diode display and a liquid crystal display. In recent times, it has been reported that the thin film transistor is also capable of being used as a driver device for various displays and image sensors. Various electronic circuits including an electronic tag may be formed on a glass or plastic substrate using the thin film transistor, and these electronic circuits are close to substantial commercialization.

The present inventors completed the present invention by conducting research on materials having novel compositions which can be used as active layers of semiconductor devices, and developing a material having a novel composition that can enhance an electrical characteristic and be obtained by a low temperature process.

### SUMMARY OF THE INVENTION

The present invention is directed to a stable and novel composition for a transparent oxide semiconductor thin film exhibiting high mobility, which is prepared by a low temperature process under 300° C.

The present invention is also directed to a field effect transistor using a stable and novel composition for a transparent oxide semiconductor thin film exhibiting high mobility, which is prepared by a low temperature process, as an active layer.

The present invention is also directed to a method of fabricating a field effect transistor using a stable and novel composition for a transparent oxide semiconductor thin film exhibiting high mobility, which is prepared by a low temperature process, as an active layer.

One aspect of the present invention provides a composition for an oxide semiconductor thin film comprising an aluminum oxide; a zinc oxide; an indium oxide; and a tin oxide, wherein the thin film formed of the composition is in amorphous phase.

In the composition for an oxide semiconductor thin film, atomic ratios of the metallic components included in the aluminum oxide, the zinc oxide, the indium oxide and the tin oxide may be 30 to 95 at % zinc, 1 to 65 at % indium, 1 to 50 at % tin, and the remainder aluminum.

The aluminum oxide may be Al₂O₃, the zinc oxide may be ZnO, the indium oxide may be In₂O₃, and the tin oxide may be SnO₂.

Another aspect of the present invention provides a field effect transistor including: source and drain electrodes, a gate insulating layer, an active layer, and a gate electrode on a substrate, wherein the active layer comprises an amorphous oxide having aluminum, zinc, indium and tin, and at least one of the source and drain electrodes and the gate electrode transmits the visible ray.

In the field effect transistor, atomic ratios of the metallic components in the oxide of the active layer may be 30 to 95 at % zinc, 1 to 65 at % indium, 1 to 50 at % tin, and the remainder aluminum.

The aluminum oxide may be Al₂O₃, the zinc oxide may be ZnO, the indium oxide may be In₂O₃, and the tin oxide may be SnO₂.

The field effect transistor according to the present invention may have a bottom-gate coplanar structure in which the gate electrode, the gate insulating layer, the source and drain electrodes and the active layer are sequentially formed on the substrate, a bottom-gate staggered structure in which the gate electrode, the gate insulating layer, the active layer and the source and drain electrodes are sequentially formed on the substrate, a top-gate staggered structure in which the source and drain electrodes, the active layer, the gate insulating layer and the gate electrode are sequentially formed on the substrate, or a top-gate coplanar structure in which the active layer, the source and drain electrodes, the gate insulating layer and the gate electrode are sequentially formed on the substrate.

Still another aspect of the present invention provides a method of fabricating a field effect transistor having a gate electrode, a gate insulating layer, an active layer and source and drain electrodes on a substrate, comprising: depositing oxides having aluminum, zinc, indium and tin at temperatures from room temperature to 300° C. to form an amorphous thin film as the active layer.

The deposition may be achieved by RF or DC magnetron sputtering, pulse laser deposition, thermal evaporation or chemical vapor deposition.

The field effect transistor may be post-annealed under 300° C.

In the field effect transistor, an electrical property of a thin film may be controlled according to an aluminum, indium or tin content in the active layer, and according to the change in oxygen partial pressure in a chamber when the active layer is formed.

### BRIEF DESCRIPTION OF THE DRAWINGS

The above and other objects, features and advantages of the present invention will become more apparent to those of ordinary skill in the art by describing in detail preferred embodiments thereof with reference to the attached drawings in which:

FIG. 1 is a cross-sectional view of a field effect transistor having a bottom-gate coplanar structure according to an exemplary embodiment of the present invention;

FIG. 2 is a cross-sectional view of a field effect transistor having a bottom-gate staggered structure according to an exemplary embodiment of the present invention;

FIG. 3 is a cross-sectional view of a field effect transistor having a top-gate staggered structure according to an exemplary embodiment of the present invention;

FIG. 4 is a cross-sectional view of a field effect transistor having a top-gate coplanar structure according to an exemplary embodiment of the present invention;

FIGS. 5 to 7 are graphs showing current-gate voltage characteristics of a bottom-gate field effect transistor, in which an active layer is formed by depositing aluminum-zinc-indium-tin oxide at room temperature and post annealing is performed at 250° C. according to exemplary embodiments of the present invention;

FIG. 8 is a graph showing current-gate voltage characteristics of a bottom gate field effect transistor, in which an active layer is formed by depositing aluminum-zinc-indium-tin oxide at room temperature according to exemplary embodiments of the present invention; and

FIG. 9 is a graph showing current-gate voltage characteristics of a bottom gate field effect transistor, in which an active layer is formed by depositing aluminum-zinc-indium-tin oxide at room temperature and post annealing is performed at 250° C. according to exemplary embodiments of the present invention.

### DETAILED DESCRIPTION OF EXEMPLARY EMBODIMENTS

Hereinafter, the present invention will be described with reference to the accompanying drawings in detail. This invention may, however, be embodied in different forms and should not be construed as limited to the embodiments set forth herein. Rather, these embodiments are provided so that this disclosure will be thorough and complete, and will fully convey the scope of the invention to those skilled in the art. Like numbers refer to like elements throughout the specification. In the drawings, the thicknesses of layers and regions are exaggerated for clarity.

The present invention provides a composition for an oxide semiconductor thin film, which includes an aluminum oxide, a zinc oxide, an indium oxide and a tin oxide. The oxide semiconductor thin film is in amorphous phase.

In the composition for an amorphous oxide semiconductor thin film including the aluminum oxide, the zinc oxide, the indium oxide and the tin oxide, atomic ratios of the metallic components, e.g. aluminum, zinc, indium and tin, may vary within the range in which the oxides remain in amorphous phase. The preferable atomic ratios of the metallic components are 30 to 95 at % zinc, 1 to 65 at % indium, 1 to 50 at % tin, and the remainder aluminum.

The aluminum oxide may be Al₂O₃, the zinc oxide may be ZnO, the indium oxide may be In₂O₃, and the tin oxide may be SnO₂.

The composition for the oxide semiconductor thin film may be generally used as an active layer in a field effect transistor.

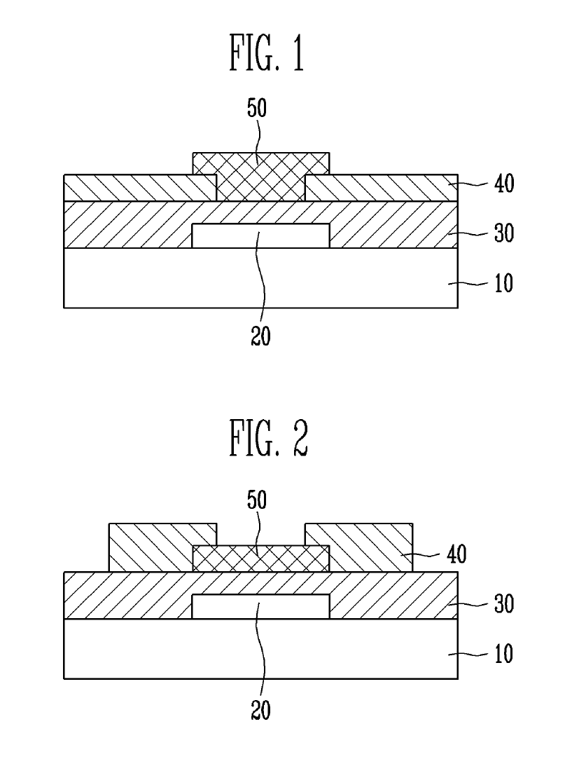

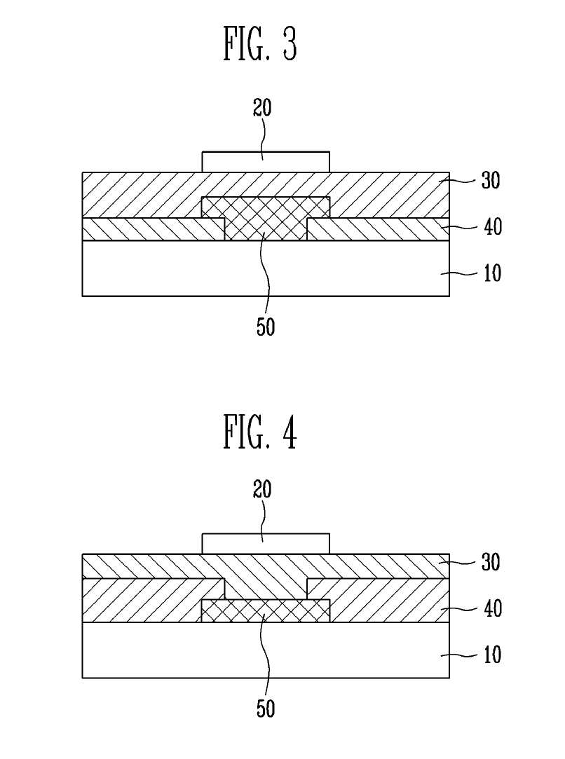

As shown in FIGS. 1 and 2, the field effect transistor may be a bottom gate field effect transistor having an inverse coplanar structure in which a gate electrode 20, a gate insulating layer 30, source and drain electrodes 40 and an active layer 50 are sequentially stacked on a substrate 10, or an inverse staggered structure in which a gate electrode 20, a gate insulating layer 30, an active layer 50 and source and drain electrodes 40 are sequentially stacked on a substrate 10. Alternatively, as shown in FIGS. 3 and 4, the field effect transistor may be a top-gate field effect transistor having a staggered structure in which source and drain electrodes 40, an active layer 50, a gate insulating layer 30 and a gate electrode 20 are sequentially stacked on a substrate 10, or a coplanar structure in which an active layer 50, source and drain electrodes 40, a gate insulating layer 30 and a gate electrode 20 are sequentially stacked on a substrate 10.

Referring to FIG. 1, the field effect transistor according to an exemplary embodiment of the present invention includes the substrate 10, the gate electrode 20, the gate insulating layer 30, the source and drain electrodes 40 and the active layer 50.

The substrate 10 may be formed of glass, metal foil, plastic or silicon.

The gate electrode 20 may be formed of, but is not limited to, a transparent oxide such as ITO (indium tin oxide), IZO (indium zinc oxide) or ZnO:Al (Ga), a metal having low resistance such as Ti, Ag, Au, Al, Cr, Al/Cr/Al or Ni, or a conductive polymer. The gate electrode 20 is deposited on the substrate 10 to a thickness commonly used in the art by sputtering, atomic layer deposition (ALD) or chemical vapor deposition (CVD), and then patterned.

The gate insulating layer 30 formed on the substrate 10 and the gate electrode 20 may include at least one selected from the transparent oxides and nitrides such as SiNx, AlON, TiO₂, AlOx, TaOx, HfOx, SiON and SiOx, and preferably aluminum oxide (Al₂O₃). Besides these examples, a polymer thin film may be used. In addition, the gate insulating layer 30 may be formed to a thickness commonly used in the art by ALD, PECVD or other sputtering techniques, and then a pad for connecting an electrode may be formed thereon although not shown in the drawing.

The source and drain electrodes 40 formed on the gate insulating layer 30 may be formed of, but are not limited to, a transparent oxide such as ITO (indium tin oxide), IZO (indium zinc oxide) or ZnO:Al(Ga), a metal such as Al, Cr, Au, Ag or Ti, or a conductive polymer. Alternatively, the source and drain electrodes 40 may be formed in a double layer structure of metal and oxide. The source and drain electrodes 40 may be deposited to a thickness commonly used in the art by sputtering, ALD or CVD, and then patterned.

The active layer 50 formed on the channel region may be formed of a composition including aluminum, zinc, indium and tin oxides, and atomic ratios of the metallic components such as aluminum, zinc, indium and tin may be 30 to 95 at % zinc, 1 to 65 at % indium, 1 to 50 at % tin, and the remainder aluminum. In addition, the aluminum oxide may be Al₂O₃, the zinc oxide may be ZnO, the indium oxide may be In₂O₃, and the tin oxide may be SnO₂.

The composition including the aluminum, zinc, indium and tin oxides may be deposited by RF/DC magnetron sputtering, pulsed laser deposition, thermal evaporation or CVD, and serve as an active layer. The composition may be deposited to about 10 to 50 nm, but the present invention is not limited thereto.

The composition including the aluminum, zinc, indium and tin oxides may be deposited at temperatures ranging from room temperature to 300° C.

A passivation layer, although not shown in the drawing, may be formed on the active layer 50. The passivation layer may be formed of a polymer such as polyimide by spin coating, dip coating or casting, and then patterned. Alternatively, the passivation layer may be formed of an insulating material, e.g., SiO₂ or Al₂O₃ by CVD or ALD, and then patterned.

All patterning processes during the formation of the thin layer may be accomplished by photolithography or wet etching.

It has been known that a ZnO, Zn—Sn—O, In—Zn—O or In—Ga—Zn—O-based oxide thin film transistor is generally annealed at a high temperature of 200° C. or higher, or formed by depositing a thin film at a high temperature in order to exhibit the field effect transistor characteristics. However, the field effect transistor using the composition comprising the aluminum-zinc-indium-tin oxide as the active layer may have transistor characteristics through deposition at room temperature, and have more excellent transistor characteristics through post annealing at temperatures ranging from 150 to 300° C.

The aluminum-zinc-indium-tin containing oxide remains in amorphous phase since it is a very chemically-stable composition, so that it is very useful in fabricating a uniform large-sized device, and still maintains stable characteristics during various high temperature processes and etching processes. Also, when the aluminum-zinc-indium-tin containing oxide according to the present invention is used for an electronic device, such as a TFT, it can maintain stable characteristics for a long time due to its high durability.

The aluminum-zinc-indium-tin containing oxide may be used as a semiconductor material for an active layer in an n-type field effect transistor, and an n-type semiconductor layer for a diode device.

Electrical properties of the aluminum-zinc-indium-tin containing oxide including electrical conductivity of a thin film may be controlled according to the content of aluminum, indium or tin. Accordingly, the electrical characteristics of the field effect transistor having the active layer formed of the oxide may be changed.

The electrical conductivity and electrical properties of the thin film formed of the aluminum-zinc-indium-tin containing oxide may be controlled according to the change in oxygen partial pressure in a chamber in the fabrication of the thin film. The electrical characteristics of the field effect transistor using the oxide as an active layer may also be changed according to the oxygen partial pressure in the fabrication of the thin film.

The electrical conductivity and electrical properties of the thin film formed of the aluminum-zinc-indium-tin containing oxide may be controlled according to a post annealing temperature and an atmosphere during the fabrication of the thin film. The electrical characteristics of the field effect transistor using the oxide as an active layer may also be controlled.

The thin film transistor using the aluminum-zinc-indium-tin containing oxide thin film as an active layer, and including source and drain electrodes, a gate electrode and a gate insulator may be applied to a back-plane device for flat display panels such as active-matrix LCD devices, active-matrix OLED display devices, and active-matrix electroluminescent display devices.

In addition, the thin film transistor using the aluminum-zinc-indium-tin containing oxide thin film as an active layer, and including source and drain electrodes, a gate electrode and a gate insulator may be applied to an inverter device for thin film-type electrical circuits.

Moreover, the thin film transistor using the aluminum-zinc-indium-tin oxide thin film as an active layer, and including source and drain electrodes, a gate electrode and a gate insulator may be applied to an amplifier device for the thin film-type electrical circuits.

Hereinafter, the present invention will be described in more detail with reference to exemplary embodiments, but is not limited to these embodiments.

### Embodiment 1

A 100 mm×100 mm alkaline-free glass substrate was sequentially cleaned with acetone, isopropyl alcohol, and deionized water using an ultrasonic bath. Subsequently, ITO was deposited on the cleaned glass substrate using a DC-RF magnetron sputter to form a gate electrode to a thickness of 150 nm, and then patterned. A gate insulator was formed by depositing alumina to a thickness of about 170 nm at 150° C. using an ALD technique, source and drain electrodes were formed to a thickness of 150 nm by depositing ITO using the DC-RF magnetron sputter and patterned. A thin film was deposited to a thickness of 30 nm on the substrate at room temperature using an RF magnetron sputter having Al₂O₃—ZnO, In₂O₃ and SnO₂ targets equipped thereto, thereby forming an active layer. The sputtering was performed in an Ar/O₂ atmosphere at a chamber pressure of 0.2 Pa by applying sputtering powers of 300 W to a cathode for the Al₂O₃—ZnO target, 100 W to a cathode for the In₂O₃ target and 30 W to a cathode for the SnO₂ target, and the patterning was performed using photolithography and wet etching. According to the above-described method, a bottom-gate coplanar type thin film transistor was fabricated, and current-voltage characteristics of the thin film transistor obtained by annealing at 250° C. were evaluated, and the result is shown in FIG. 5. The field effect mobility of the device was estimated at 16 cm²/Vs.

### Embodiment 2

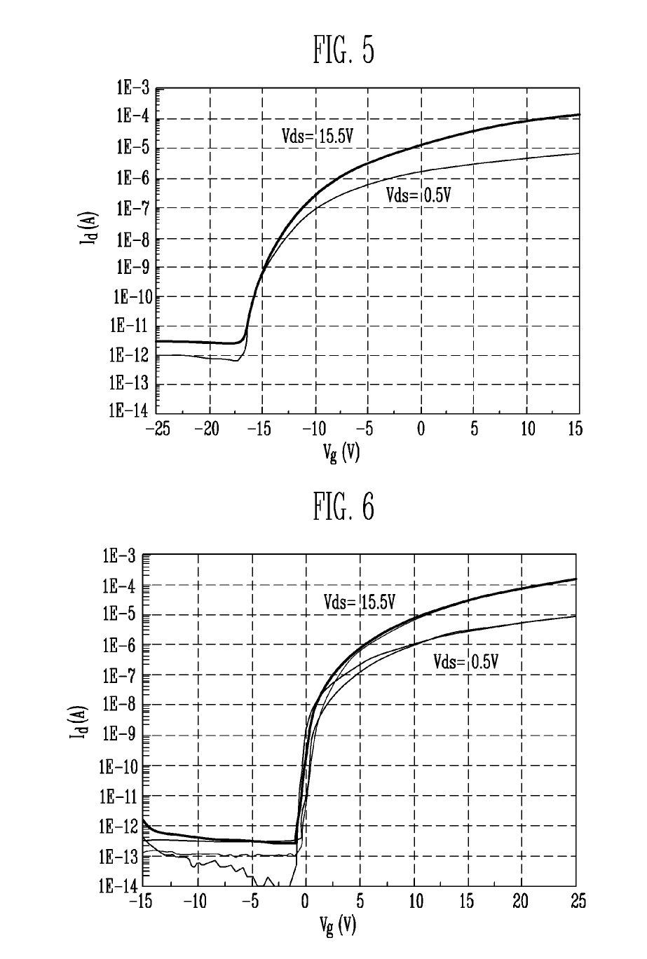

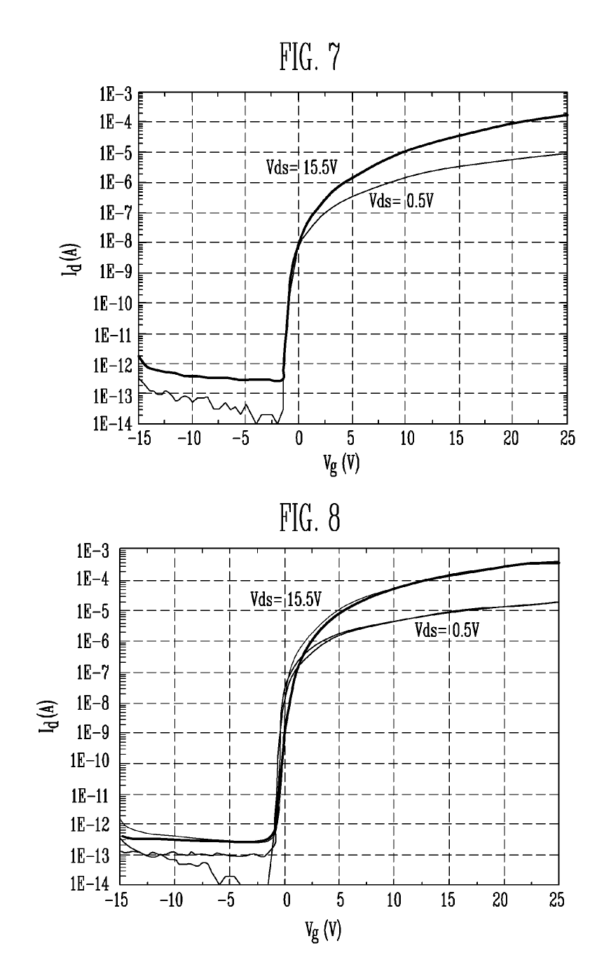

A 100 mm×100 mm alkaline-free glass substrate was sequentially cleaned with acetone, isopropyl alcohol, and deionized water using an ultrasonic bath. Subsequently, ITO was deposited on the cleaned glass substrate using a DC-RF magnetron sputter to form a gate electrode to a thickness of 150 nm, and then patterned. A gate insulator was formed by depositing alumina to a thickness of about 170 nm at 150° C. using an ALD technique, source and drain electrodes were formed to a thickness of 150 nm by depositing ITO using the DC-RF magnetron sputter and patterned. A thin film was deposited to a thickness of 30 nm on the substrate at room temperature using an RF magnetron sputter having Al₂O₃—ZnO, In₂O₃ and SnO₂ targets equipped thereto, thereby forming an active layer. The sputtering was performed in an Ar/O₂ atmosphere at a chamber pressure of 0.2 Pa by applying sputtering powers of 300 W to a cathode for the Al₂O₃—ZnO target, 150 W to a cathode for the In₂O₃ target and 30 W to a cathode for the SnO₂ target, and the patterning was performed using photolithography and wet etching. According to the above-described method, a bottom-gate coplanar type thin film transistor was fabricated, and current-voltage characteristics of the thin film transistor obtained by annealing at 250° C. were evaluated, and the result is shown in FIG. 6. The field effect mobility of the device was estimated at 25 cm²/Vs.

### Embodiment 3

A 100 mm×100 mm alkaline-free glass substrate was sequentially cleaned with acetone, isopropyl alcohol, and deionized water using an ultrasonic bath. Subsequently, ITO was deposited on the cleaned glass substrate using a DC-RF magnetron sputter to form a gate electrode to a thickness of 150 nm, and then patterned. A gate insulator was formed by depositing alumina to a thickness of about 170 nm at 150° C. using an ALD technique, source and drain electrodes were formed to a thickness of 150 nm by depositing ITO using the DC-RF magnetron sputter and patterned. A thin film was deposited to a thickness of 30 nm on the substrate at room temperature using an RF magnetron sputter having Al₂O₃—ZnO, In₂O₃ and SnO₂ targets equipped thereto, thereby forming an active layer. The sputtering was performed in an Ar/O₂ atmosphere at a chamber pressure of 0.2 Pa by applying sputtering powers of 300 W to a cathode for the Al₂O₃—ZnO target, 180 W to a cathode for the In₂O₃ target and 30 W to a cathode for the SnO₂ target, and the patterning was performed using photolithography and wet etching. According to the above-described method, a bottom-gate coplanar type thin film transistor was fabricated, and current-voltage characteristics of the thin film transistor obtained by annealing at 250° C. were evaluated, and the result is shown in FIG. 7. The field effect mobility of the device was estimated at 29 cm²/Vs.

### Embodiment 4

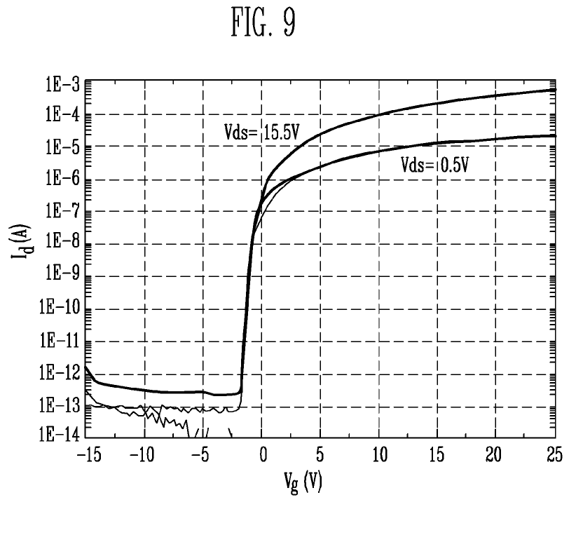

A 100 mm×100 mm alkaline-free glass substrate was sequentially cleaned with acetone, isopropyl alcohol, and deionized water using an ultrasonic bath. Subsequently, ITO was deposited on the cleaned glass substrate using a DC-RF magnetron sputter to form a gate electrode to a thickness of 150 nm, and then patterned. A gate insulator was formed by depositing alumina to a thickness of about 170 nm at 150° C. using an ALD technique, source and drain electrodes were formed to a thickness of 150 nm by depositing ITO using the DC-RF magnetron sputter and patterned. A thin film was deposited to a thickness of 30 nm on the substrate at room temperature using an RF magnetron sputter having Al₂O₃—ZnO, In₂O₃ and SnO₂ targets equipped thereto, thereby forming an active layer. The sputtering was performed in an Ar/O₂ atmosphere at a chamber pressure of 0.2 Pa by applying sputtering powers of 300 W to a cathode for the Al₂O₃—ZnO target, 100 W to a cathode for the In₂O₃ target and 60 W to a cathode for the SnO₂ target, and the patterning was performed using photolithography and wet etching. According to the above-described method, a bottom-gate coplanar type thin film transistor was fabricated, and current-voltage characteristics of the thin film transistor were evaluated, and the result is shown in FIG. 8. The field effect mobility of the device was estimated at 9 cm²/Vs.

### Embodiment 5

Other than annealing the fabricated device for one hour in an oxygen atmosphere at 250° C., a thin film transistor device was fabricated as described in Embodiment 4. Subsequently, current-voltage characteristics of the thin film transistor were evaluated, and the result is shown in FIG. 9. The field effect mobility of the device was estimated at 14 cm²/Vs.

According to Embodiments 1 to 3, as the In content is increased, i.e., power applied to the In target is raised, it can be confirmed that the mobility of the device is increased. According to Embodiments 1 and 4, as the Sn content is increased, i.e., power applied to the Sn target is raised, it can be confirmed that the mobility of the device is decreased. Therefore, it is noted that the electrical characteristics of the device can be controlled according to the In or Sn content.

Using a composition for an oxide semiconductor thin film including an aluminum oxide, a zinc oxide, an indium oxide and a tin oxide, a stable and transparent oxide semiconductor thin film exhibiting high mobility can be formed by a low temperature process at 300° C. or lower.

Further, using a composition for an oxide semiconductor thin film including an aluminum oxide, a zinc oxide, an indium oxide and a tin oxide, a transparent oxide semiconductor thin film can be formed without using a toxic heavy metallic component such as Cd or Pb.

The composition for the oxide semiconductor thin film according to the present invention is used as an active layer through the low temperature process at 300° C. or less, thereby obtaining good thin film transistor characteristics.

Using the composition for the oxide semiconductor thin film according to the present invention, a thin film transistor device may be formed using a low temperature substrate such as a plastic substrate requiring a process temperature under 200° C.

The composition for the oxide semiconductor thin film according to the present invention is chemically very stable and has excellent durability.

Using the composition for the oxide semiconductor thin film according to the present invention, an amorphous thin film can be easily formed through room temperature deposition, which is preferable in fabricating a uniform large-sized electronic device.

Using the composition for the oxide semiconductor thin film, a semiconductor thin film having an excellent thin film characteristic can be formed through room temperature sputtering, which is preferable in fabricating a large-sized electronic device at a low cost.

The composition for the oxide semiconductor thin film according to the present invention can be used for an active layer to fabricate a transparent electronic device having a visible-ray transmittance of 70% or higher.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A composition for an oxide semiconductor thin film, comprising:
an aluminum oxide;
a zinc oxide;
an indium oxide; and
a tin oxide,
wherein the thin film formed of the composition is in amorphous phase.

2. The composition according to claim 1, wherein the atomic rations metallic components included in the aluminum oxide, the zinc oxide, the indium oxide and the tin oxide are 30 to 95 at % zinc, 1 to 65 at % indium, 1 to 50 at % tin, and the remainder aluminum.

3. The composition according to claim 1, wherein the aluminum oxide is Al₂O₃, the zinc oxide is ZnO, the indium oxide is In₂O₃, and the tin oxide is SnO₂.

4. A field effect transistor, comprising:
source and drain electrodes, a gate insulating layer, an active layer, and a gate electrode formed on a substrate,
wherein the active layer comprises an amorphous oxide having aluminum, zinc, indium and tin, and at least one of the source and drain electrodes and the gate electrode transmits the visible ray.

5. The field effect transistor according to claim 4, wherein atomic ratios of the metallic components in the oxide of the active layer are 30 to 95 at % zinc, 1 to 65 at % indium, 1 to 50 at % tin, and the remainder aluminum.

6. The field effect transistor according to claim 4, wherein the aluminum oxide is Al₂O₃, the zinc oxide is ZnO, the indium oxide is In₂O₃, and the tin oxide is SnO₂.

7. The field effect transistor according to claim 4, wherein an electrical property of the thin film is controlled according to an aluminum, indium or tin content in the active layer.

8. The field effect transistor according to claim 4, wherein the gate electrode, the gate insulating layer, the source and drain electrodes and the active layer are sequentially formed on the substrate to form a bottom-gate coplanar structure.

9. The field effect transistor according to claim 4, wherein the gate electrode, the gate insulating layer, the active layer and the source and drain electrodes are sequentially formed on the substrate to form a bottom-gate staggered structure.

10. The field effect transistor according to claim 4, wherein the source and drain electrodes, the active layer, the gate insulating layer and the gate electrode are sequentially formed on the substrate to form a top-gate staggered structure.

11. The field effect transistor according to claim 4, wherein the active layer, the source and drain electrodes, the gate insulating layer and the gate electrode are sequentially formed on the substrate to form a top-gate coplanar structure.

12. A method of fabricating a field effect transistor comprising a gate electrode, a gate insulating layer, an active layer and source and drain electrodes formed on a substrate, the method comprising:
depositing oxides containing aluminum, zinc, indium and tin at temperatures ranging from room temperature to 300° C. to form an amorphous thin film as the active layer.

13. The method according to claim 12, wherein the active layer is deposited by RF or DC magnetron sputtering, pulse laser deposition, thermal evaporation or chemical vapor deposition.

14. The method according to claim 12, wherein the thin film transistor is post-annealed at a temperature of 300° C. or lower.

15. The method according to claim 12, wherein an electrical property of the field effect transistor is controlled according to a change in oxygen partial pressure in a chamber when the active layer is formed.
